(19) United States
(12) Patent Application Publication
(10) Pub. No.: US 2019/0019568 A1
(43) Pub. Date: Jan. 17, 2019

(54) FUSE-BLOWING SYSTEM AND METHOD FOR OPERATING THE SAME

(71) Applicant: Nanya Technology Corporation, New Taipei City (TW)

(72) Inventors: Ting-Shuo HSU, New Taipei City (TW); Chih-Wei SHEN, Yunlin County (TW)

(21) Appl. No.: 15/647,788

(22) Filed: Jul. 12, 2017

(51) Int. Cl. G11C 29/00; G11C 11/408

(52) U.S. Cl. CPC G11C 29/785; G11C 2029/1208; G11C 11/4087

(57) ABSTRACT

The present disclosure provides a fuse-blowing system of a dynamic random access memory (DRAM). The fuse-blowing system includes a fuse device and a mapping device. The mapping device, integrated with the fuse device in the DRAM, enables the fuse device and provides the fuse device with a physical address. The enabled fuse device, in response to only the provided physical address, performs a fuse-blowing operation on a fuse of the DRAM.

### TECHNICAL FIELD

The present disclosure relates to a dynamic random access memory (DRAM), and more particularly, to a fuse-blowing system of a DRAM.

### DISCUSSION OF THE BACKGROUND

With the development of miniaturized memory elements manufactured by complex fabrication processes, the memory elements are increasingly prone to various performance-limiting defects. Currently, fuses and e-fuses are most commonly applied to solving the problems caused by the various defects, with both fuses and e-fuses being utilized in complex repair methods to solve such problems.

This Discussion of the Background section is for background information only. The statements in this Discussion of the Background are not an admission that the subject matter disclosed in this section constitutes a prior art to the present disclosure, and no part of this section may be used as an admission that any part of this application, including this Discussion of the Background section, constitutes prior art to the present disclosure.

### SUMMARY

One aspect of the present disclosure provides a fuse-blowing system of a dynamic random access memory (DRAM). The fuse-blowing system includes a fuse device and a mapping device. The mapping device, integrated with the fuse device in the DRAM, enables the fuse device, and provides the fuse device with a physical address. The enabled fuse device, in response to only the provided physical address, performs a fuse-blowing operation on a fuse of the DRAM.

In some embodiments, the mapping device is further configured to receive, from a device external to the DRAM, an information including a logical address of a normal word line of the DRAM, wherein the normal word line contains defects, and the mapping device provides the fuse device with the physical address to which the logical address maps.

In some embodiments, the mapping device is further configured to receive from the device a command instructing to perform the fuse-blowing operation, and the mapping device enables the fuse device in response to the received command.

In some embodiments, the enabled fuse device is further configured to, in response to only the provided physical address, perform the fuse-blowing operation on the fuse if the provided physical address has not previously been received.

In some embodiments, if the provided physical address is one that has previously been received, the enabled fuse device is further configured to, in response to only the provided physical address, perform the fuse-blowing operation on a fuse other than a fuse on which the fuse-blowing operation was previously performed.

In some embodiments, the fuse on which the fuse-blowing operation is performed is immediately adjacent to the fuse on which the fuse-blowing operation was previously performed.

In some embodiments, the fuse on which the fuse-blowing operation is performed is immediately adjacent to a fuse immediately adjacent to the fuse on which the fuse-blowing operation was previously performed.

In some embodiments, the DRAM includes a double-data-rate three synchronous dynamic random access memory (DDR3).

In some embodiments, the fuse includes a laser-fusible fuse.

Another aspect of the present disclosure provides a fuse-blowing system of a dynamic random access memory (DRAM). The fuse-blowing system includes a fuse device, a first fuse, a second fuse and a mapping device. The first fuse is fusible by the fuse device. The second fuse is fusible by the fuse device. The mapping device, integrated with the fuse device in the DRAM, enables the fuse device, and provides the fuse device with a physical address for a first time. The enabled fuse device, in response to only the provided physical address for the first time, performs a fuse-blowing operation on the first fuse. When the mapping device enables the fuse device and provides the fuse device with the physical address for a second time, the enabled fuse device, in response to only the provided physical address for the second time, performs the fuse-blowing operation on the second fuse.

In some embodiments, the mapping device is further configured to receive, from a device external to the DRAM, an information including a logical address of a normal word line of the DRAM, wherein the normal word line contains defects, and the mapping device provides the fuse device with the physical address to which the logical address maps.

In some embodiments, the mapping device is further configured to receive from the device a command to perform the fuse-blowing operation, and enables the fuse device in response to the received command.

In some embodiments, the second fuse is immediately adjacent to the first fuse.

In some embodiments, the second fuse is immediately adjacent to a fuse immediately adjacent to the first fuse.

In some embodiments, the DRAM includes a double-data-rate three synchronous dynamic random access memory (DDR3).

In some embodiments, the fuse includes a laser-fusible fuse.

Another aspect of the present disclosure provides a method of operating a fuse-blowing system of a DRAM. The method includes enabling a fuse device of the fuse-blowing system; providing the fuse device with a physical address; and performing, in response to only the provided physical address, a fuse-blowing operation on a fuse of the DRAM by the enabled fuse device.

In some embodiments, the method further includes receiving, from a device external to the DRAM, an information including a logical address of a normal word line of the DRAM, wherein the normal word line contains defects; and providing the fuse device with the physical address to which the logical address maps.

In some embodiments, the method further includes receiving from the device a command instructing to perform a fuse-blowing operation; and enabling the fuse device in response to the received command.

In some embodiments, the method further includes performing, in response to only the provided physical address, and when the provided physical address has not previously been received, the fuse-blowing operation on the fuse by the enabled fuse device.

In the present disclosure, with the mapping device functioning to map the logical address of a normal word line of the DRAM to the physical address of the normal word line, even though a client never knows the physical address (i.e., the client is not able to provide the physical address to the DRAM) and only knows the logical address, the client still can perform the fuse-blowing operation to blow the fuse by providing the logical address to the DRAM.

In contrast, during operation of some DRAMs, for a client who does not possess physical addresses of the DRAMs, and only possesses logical addresses, there is no way for the client to perform a fuse-blowing operation. Problems on a normal word line that contains defects cannot be fixed. As a result, usage of the DRAMs is limited and less convenient for the client due to limitations of the design of the DRAMs.

Moreover, in the present disclosure, as mentioned above the mapping device is able to provide the fuse device with the physical address of the normal word line. The fuse device only requires the physical address provided by the mapping device instead of being provided by the client to perform the fuse-blowing operation. Besides the physical address and the command, no other information or operations are required. Therefore, operations of the DRAM are relatively simple.

In contrast, during operation of some DRAMs, in a post package repair (PPR) function, to perform an operation similar to the fuse-blowing operation mentioned above, a client must not only provide a logical address of a normal word line containing defects to the DRAMs, but also must provide a lot of additional information besides the logical address, and a lot of operations are required to be performed. In such DRAMs, the operations are relatively complicated.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be connected to the figures' reference numbers, which refer to similar elements throughout the description, and:

FIG. 1 is a schematic diagram of a comparative dynamic random access memory (DRAM), which includes a fuse-blowing system.

FIG. 2 is a schematic diagram of a DRAM, which includes a fuse-blowing system, in accordance with some embodiments of the present disclosure.

FIG. 3 is a schematic diagram illustrating an operation of the DRAM shown in FIG. 2, in accordance with some embodiments of the present disclosure.

FIG. 4 is a schematic diagram of another DRAM, which includes a fuse-blowing system, in accordance with some embodiments of the present disclosure.

FIG. 5 is a schematic diagram illustrating an operation of the DRAM shown in FIG. 4 in a circumstance, in accordance with some embodiments of the present disclosure.

FIG. 6 is a schematic diagram illustrating an event of the circumstance, in accordance with some embodiments of the present disclosure.

FIG. 7 is a schematic diagram illustrating an operation of the DRAM shown in FIG. 4 in the event, in accordance with some embodiments of the present disclosure.

FIG. 8 is a schematic diagram illustrating the operation of the DRAM shown in FIG. 4 in the event, in accordance with some embodiments of the present disclosure.

FIG. 9 is a flow diagram illustrating a method of operating a fuse-blowing system of a DRAM, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that when an element is referred to as being “connected to” or “coupled with” another element, the initial element may be directly connected to, or coupled to, another element, or to other intervening elements.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

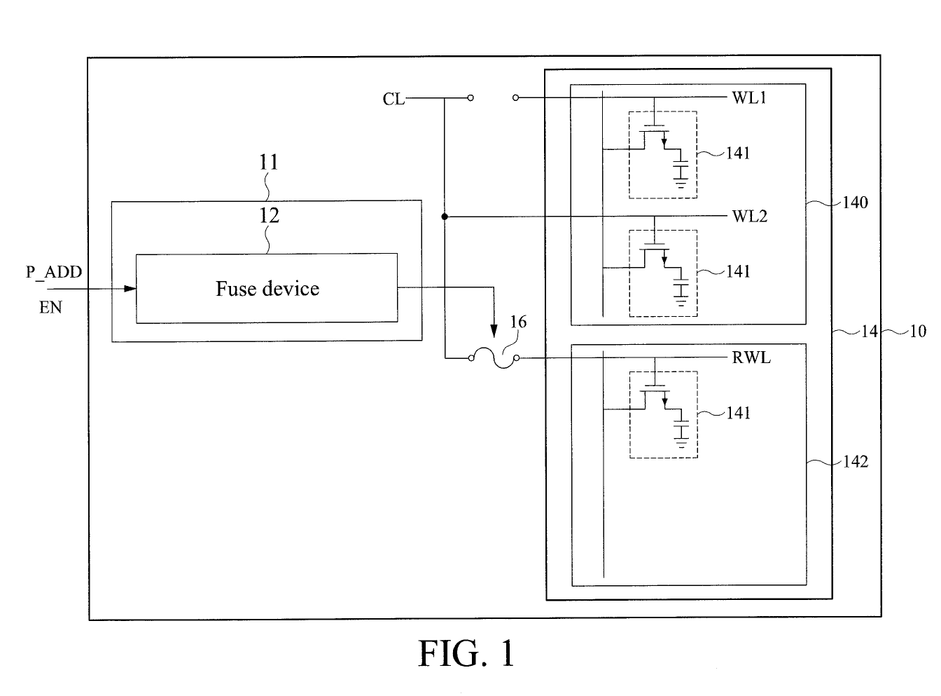

FIG. 1 is a schematic diagram of a comparative dynamic random access memory (DRAM) 10, which includes a fuse-blowing system 11. Referring to FIG. 1, in addition to the fuse-blowing system 11, which includes a fuse device 12, the DRAM 10 further includes a fuse 16, and a bank 14 which includes a normal memory block 140 and a redundant memory block 142.

The normal memory block 140 includes an array of memory cells 141. Each of the memory cells is able to store a single bit of information. A specific bit within the array of the normal memory block 140 is specified by a particular address. For the sake of simplicity of illustration and discussion, only two memory cells 141 and the two associated normal word lines WL1 and WL2 are depicted. Memory cells 141 in the same row are accessed by the same normal word line in normal memory block 140. For example, a memory cell 141 in a row is accessed by a normal word line WL1, and a memory cell 141 in another row is accessed by another normal word line WL2. In addition, as shown in FIG. 1, the normal word line WL1 is a normal word line containing defects. In further detail, an open circuit occurs on the normal word line WL1, and such open circuit may result from the semiconductor manufacturing process. As such, the normal word line WL1 is disconnected from a control line CL, which controls accesses of normal word lines of the DRAM 10. Consequently, the normal word line WL1 is inoperable and is unable to be accessed.

The redundant memory block 142 includes an array of memory cells 141. Each memory cell 141 is able to store a single bit of information. A specific bit within the array of the redundant memory block 142 is specified by a particular address. For the sake of simplicity of illustration, only a single memory cell 141 and the single associated redundant word line RWL are depicted. Redundant word lines of the redundant memory block 142 are used to replace any normal word lines in the normal memory block 140 that contain defects. Such redundant word lines are able to be accessed after a fuse-blowing operation, which will be described in detail below, is performed. In the present embodiment, the redundant word line RWL can be used to replace the normal word line WL1.

The fuse 16 is fusible by the fuse device 12, and connects the redundant word line RWL to the control line CL after the fuse 16 is blown in the fuse-blowing operation. In an embodiment, the fuse 16 is a laser-fusible link that is typically composed of polysilicon or metal and is covered by a uniform layer of dielectric, such as silicon dioxide.

The fuse device 12 is notified of the normal word line WL containing defects based on a physical address P_ADD of the normal word line WL, wherein the physical address P_ADD is received from a testing station at a foundry. In addition, the fuse device 12 is enabled in response to an enable signal EN. After the fuse device 12 is enabled, the fuse device 12 performs the fuse-blowing operation on the fuse 16, such that the fuse 16 is blown and the blown fuse 16 connects the redundant word line RWL to the control line CL. As a result, the redundant word line RWL is operable and able to be accessed.

In further detail, after the DRAM 10 fabrication, tests are performed on the DRAM 10 to determine which, if any, word lines of the DRAM 10 have defects. In the example of FIG. 1, during testing, the foundry that makes the DRAM 10 finds that the normal word line WL1 containing defects. To fix such problem, the testing station at the foundry enables the fuse device 12 by providing the physical address P_ADD of the normal word line WL1 and the enable signal EN to the fuse device 12. Consequently, as previously mentioned, the redundant word line RWL replaces the normal word line WL1, and the redundant word line RWL is able to be accessed.

It should be noted that physical addresses, such as the physical address P_ADD of the normal word line WL1, of a DRAM are classified information and are owned by the foundry. The foundry may not willingly provide the physical addresses to anyone, including a client. The client therefore does not possess the physical addresses, and possesses only logical addresses of the DRAM. Without the physical addresses, under prior designs, there is no way for the client to perform the fuse-blowing operation. Problems incurred by a normal word line containing defects, analogous to the normal word line WL1, cannot be fixed. As a result, usage of the DRAM 10 is limited and less convenient for the client due to limitations of the design of the DRAM 10.

Moreover, during operation of some DRAMs, in a post package repair (PPR) function, to perform an operation similar to the fuse-blowing operation mentioned above, a client must not only provide a logical address of a normal word line containing defects to the DRAMs, but also must provide a lot of additional information besides the logical address, and a lot of operations are required to be performed. In such DRAMs, the operations are relatively complicated.

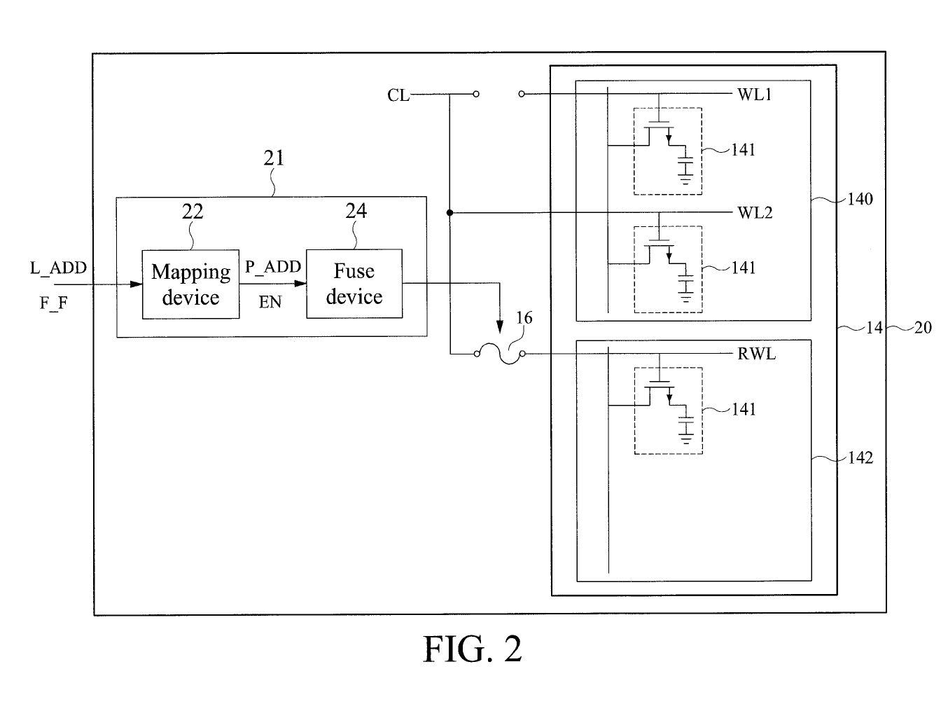

FIG. 2 is a schematic diagram of a DRAM 20 which includes a fuse-blowing system 21, in accordance with some embodiments of the present disclosure. In an embodiment, the DRAM 20 includes a double-data-rate three synchronous dynamic random access memory (DDR3). Referring to FIG. 2, the fuse-blowing system 21 is similar to the fuse-blowing system 11 described and illustrated with reference to FIG. 1 except that, for example, the fuse-blowing system 21 includes a mapping device 22 and a fuse device 24.

The mapping device 22, integrated with the fuse device 24 in the DRAM 20, functions to receive, from a device (not shown) external to the DRAM 20, a command F_F instructing to perform a fuse-blowing operation. The mapping device 22 enables the fuse device 24 in response to the received command F_F. In addition, the mapping device 22 further receives from the device (not shown) an information including a logical address L_ADD of a normal word line s1 of the DRAM 20, wherein the normal word line contains defects. The mapping device 22 provides the fuse device 24 with a physical address P_ADD to which the logical address L_ADD maps. With the mapping device 22 functioning to map the logical address to the physical address, even though a client never know the physical addresses of the normal word lines of the DRAM 20, the client still can perform the fuse-blowing operation on the fuse 16 by providing the logical address to the DRAM 20. As a result, usage of the DRAM 20 is easier and more convenient for the client. In an embodiment, the fuse 16 includes a laser-fusible fuse.

The fuse device 24 functions to, in response to only the provided physical address P_ADD, perform a fuse-blowing operation on a fuse 16 of the DRAM 20 when the fuse device 24 is enabled. That is, the fuse device 24 requires only the physical address P_ADD to perform the fuse-blowing operation. Besides the physical address P_ADD and the command F_F, no other information or operations are required. Therefore, operations of the DRAM 20 are relatively simple. After the fuse-blowing operation is performed, the fuse 16 is blown. Consequently, the redundant word line RWL is connected to the control line CL and therefore is operable and able to be accessed.

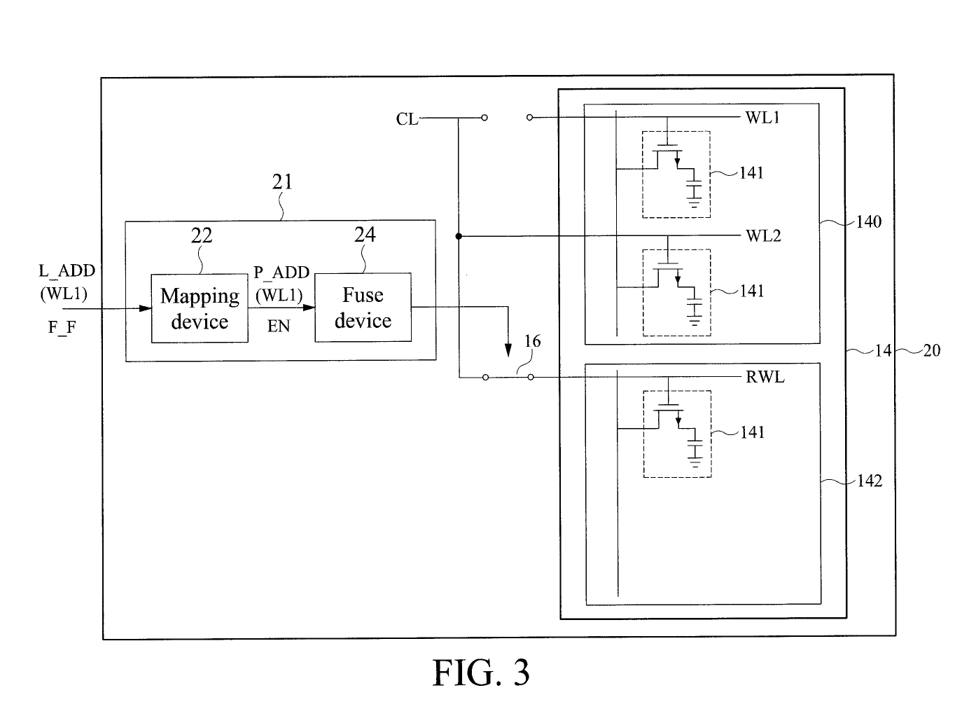

FIG. 3 is a schematic diagram illustrating an operation of the DRAM 20 shown in FIG. 2, in accordance with some embodiments of the present disclosure. Referring to FIG. 3, the mapping device 22 receives, from the device (not shown) external to the DRAM 20, a command F_F instructing to perform a fuse-blowing operation, and the mapping device 22 enables the fuse device 24 by providing an enable signal EN to the fuse device 24 in response to the received command F_F. In addition, the mapping device 22 further receives from the device (not shown) an information including a logical address L_ADD (WL1) of the normal word line WL1 containing defects, and the mapping device 22 provides the fuse device 24 with a physical address P_ADD (WL1) to which the logical address L_ADD (WL1) maps. In response to only the provided physical address P_ADD (WL1), the enabled fuse device 24 performs the fuse-blowing operation on the fuse 16. The blown fuse 16 connects the redundant word line RWL to the control line CL. As a result, the redundant word line RWL is operable and able to be accessed. After the fuse-blowing operation is completed, the fuse-blowing system 41 is disabled so that an access operation can be performed.

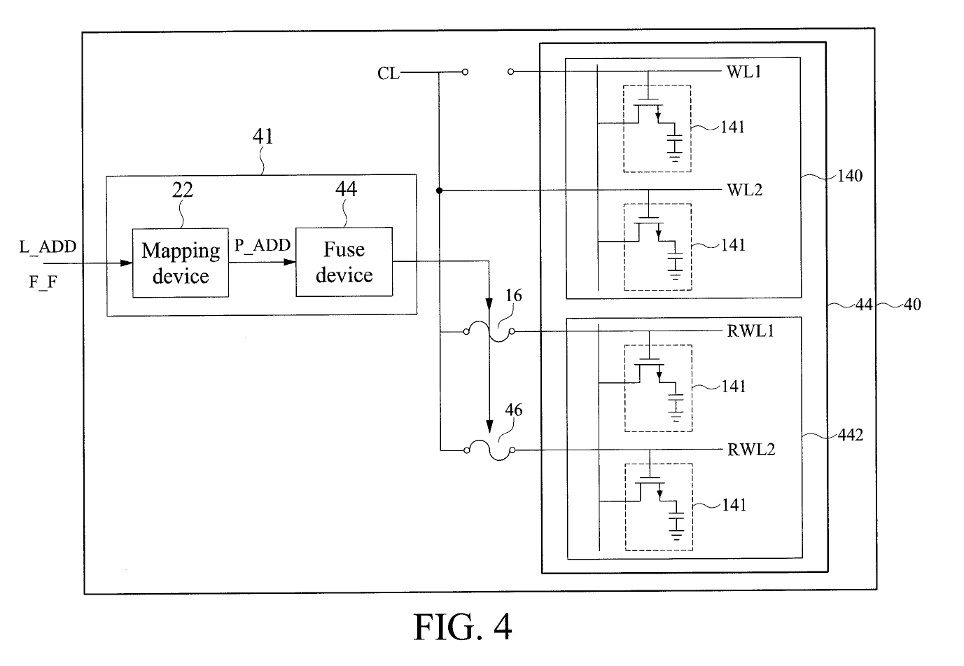

FIG. 4 is a schematic diagram of another DRAM 40, which includes a fuse-blowing system 41, in accordance with some embodiments of the present disclosure. Referring to FIG. 4, the fuse-blowing system 41 is similar to the fuse-blowing system 21 described and illustrated with reference to FIG. 2 except that, for example, the fuse-blowing system 21 includes a fuse device 44.

Moreover, the DRAM 40 includes a bank 44 including a redundant memory block 442, which is similar to the redundant memory block 142 described and illustrated with reference to FIG. 2 except that, for example, the redundant memory block 442 further includes a redundant word line RWL2. For convenience of discussion, a redundant word line RWL1 is identified as a first redundant word line RWL1, and the redundant word line RWL2 is identified as a second redundant word line RWL2.

Additionally, the DRAM 40 further includes a fuse 46 in addition to the fuse 16. For convenience of discussion, the fuse 16 is identified as a first fuse 16, and the fuse 46 is identified as a second fuse 46. In an embodiment, the second fuse 46 is immediately adjacent to the first fuse 16. In another embodiment, the second fuse 46 is immediately adjacent to a fuse immediately adjacent to the first fuse 16.

Some operations of the mapping device 22 and the fuse device 44 are substantially the same as those of the mapping device 22 and the fuse device 24 discussed in the embodiments of FIGS. 2 and 3. Therefore, some detailed descriptions are omitted herein.

The mapping device 22 receives a logical address L_ADD for a first time, and the mapping device 22 provides the fuse device 44 with a physical address P_ADD, to which the logical address L_ADD maps, for a first time. The enabled fuse device 44, in response to only the provided physical address P_ADD for the first time, performs a fuse-blowing operation on the first fuse 16. The blown fuse 16 connects the first redundant word line RWL1 to the control line CL.

However, an open circuit may occur on the first redundant word line RWL1, wherein the open circuit results from an accidental error operation on the first redundant word line RWL1, such that the operable first redundant word line RWL1 may no longer be operable. In such circumstance, a client may provide the same logical address L_ADD to the DRAM 40. If the mapping device 22 receives the same logical address L_ADD for a second time, the mapping device 22 provides the fuse device 44 with the same physical address P_ADD for a second time. The enabled fuse device 44, in response to only the provided physical address P_ADD for the second time, performs the fuse-blowing operation on the second fuse 46. As a result, the second redundant word line RWL2 replaces the normal word line WL1 and the second redundant word line RWL2 is able to be accessed. Accordingly, the DRAM 40 is more convenient for the client to use.

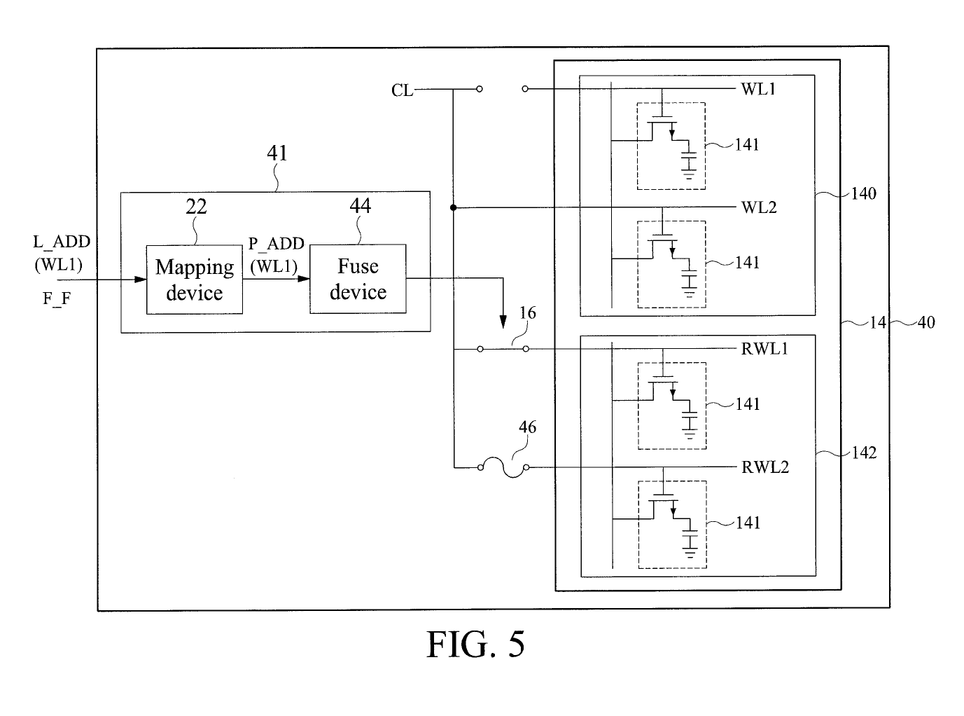

FIG. 5 is a schematic diagram illustrating an operation of the DRAM 40 shown in FIG. 4 in a circumstance, in accordance with some embodiments of the present disclosure. Referring to FIG. 5, the mapping device 22 receives a logical address L_ADD (WL1) of the normal word line WL1 for a first time, and the mapping device 22 provides the fuse device 44 with a physical address P_ADD (WL1), to which the logical address L_ADD (WL1) maps, for a first time. The enabled fuse device 44, in response to only the provided physical address P_ADD (WL1) for the first time, performs a fuse-blowing operation on the first fuse 16. The blown fuse 16 connects the first redundant word line RWL1 to the control line CL.

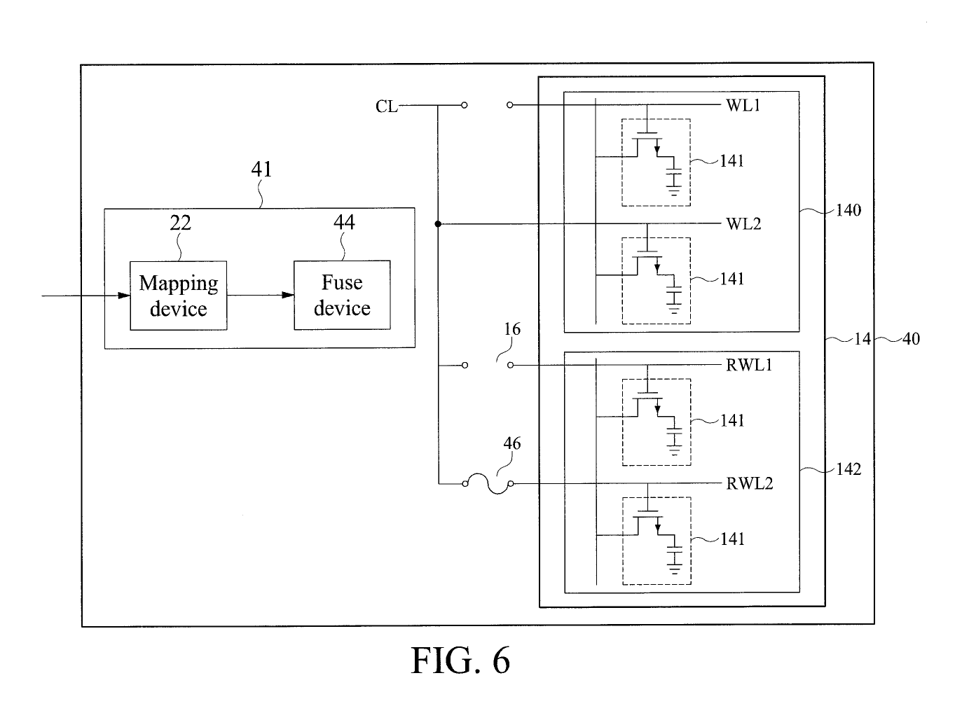

FIG. 6 is a schematic diagram illustrating an event of the circumstance, in accordance with some embodiments of the present disclosure. Referring to FIG. 6, an open circuit occurs on the first redundant word line RWL1, wherein the open circuit may result from an accidental error operation on the first redundant word line RWL1, such that the operable first redundant word line RWL1 may no longer be operable.

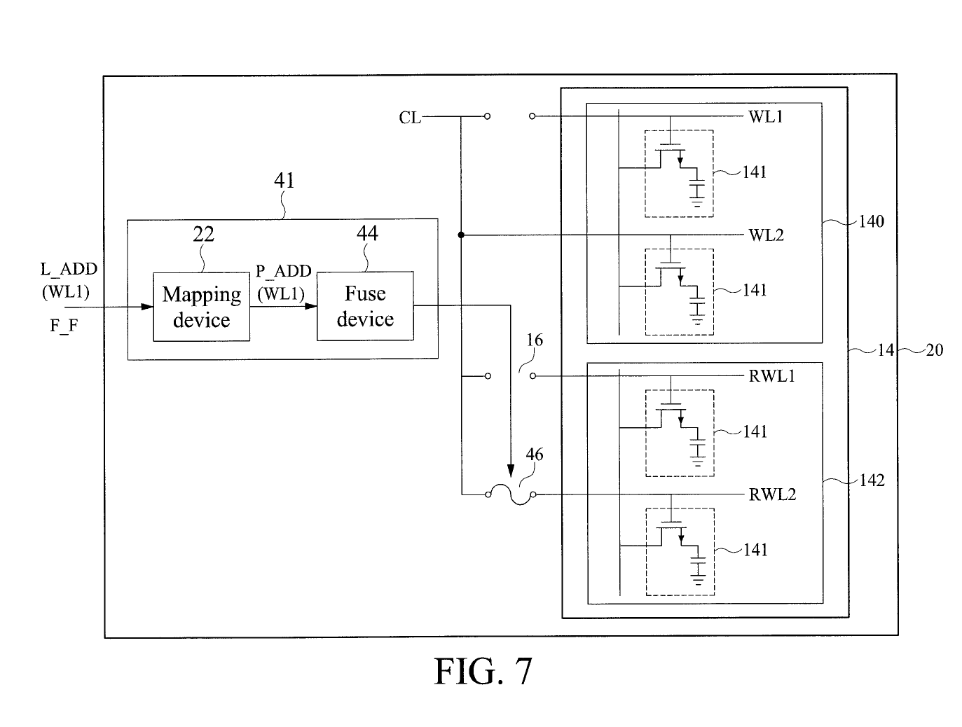

FIG. 7 is a schematic diagram illustrating an operation of the DRAM 40 shown in FIG. 4 in the event, in accordance with some embodiments of the present disclosure. Referring to FIG. 7, the mapping device 22 receives the same logical address L_ADD (WL1) for the second time, and provides the fuse device 44 with the same physical address P_ADD (WL1) for the second time. The fuse device 44 determines that the same physical address P_ADD (WL1) has been 15s previously received. Therefore, the enabled fuse device 44, in response to the same physical address P_ADD (WL1) for the second time, performs a fuse-blowing operation on the second fuse 46.

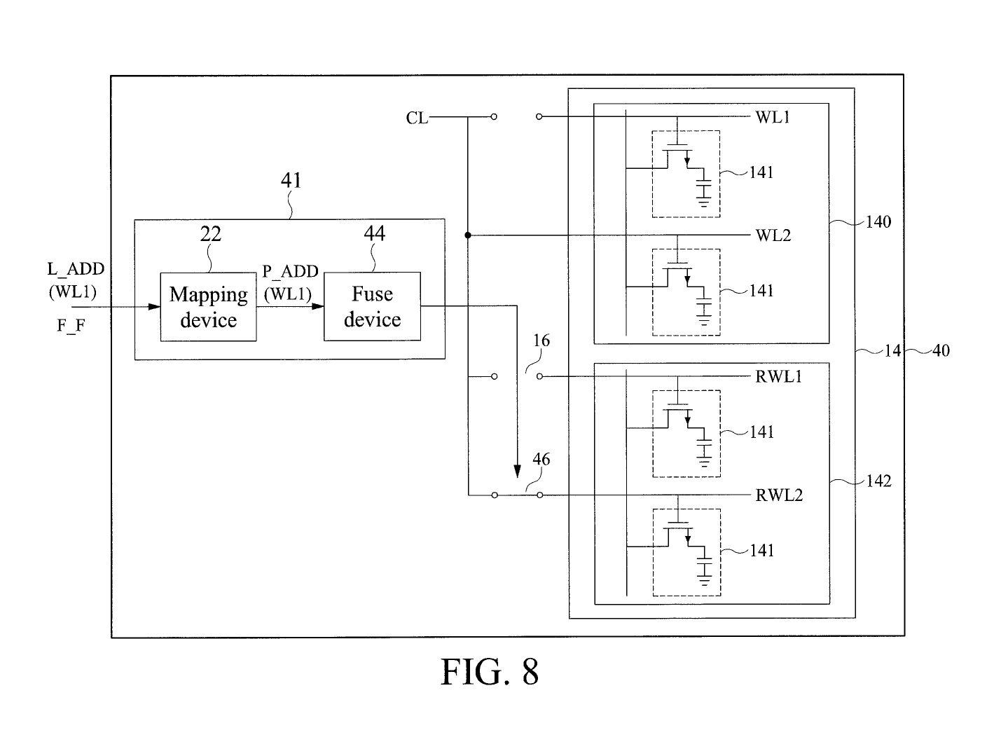

FIG. 8 is a schematic diagram illustrating the operation of the DRAM shown in FIG. 4 in the event, in accordance with some embodiments of the present disclosure. Referring to FIG. 8, the blown second fuse 46 connects the second redundant word line RWL2 to the control line CL. The second redundant word line RWL2 replaces the normal word line WL1, and the second redundant word line is able to be accessed.

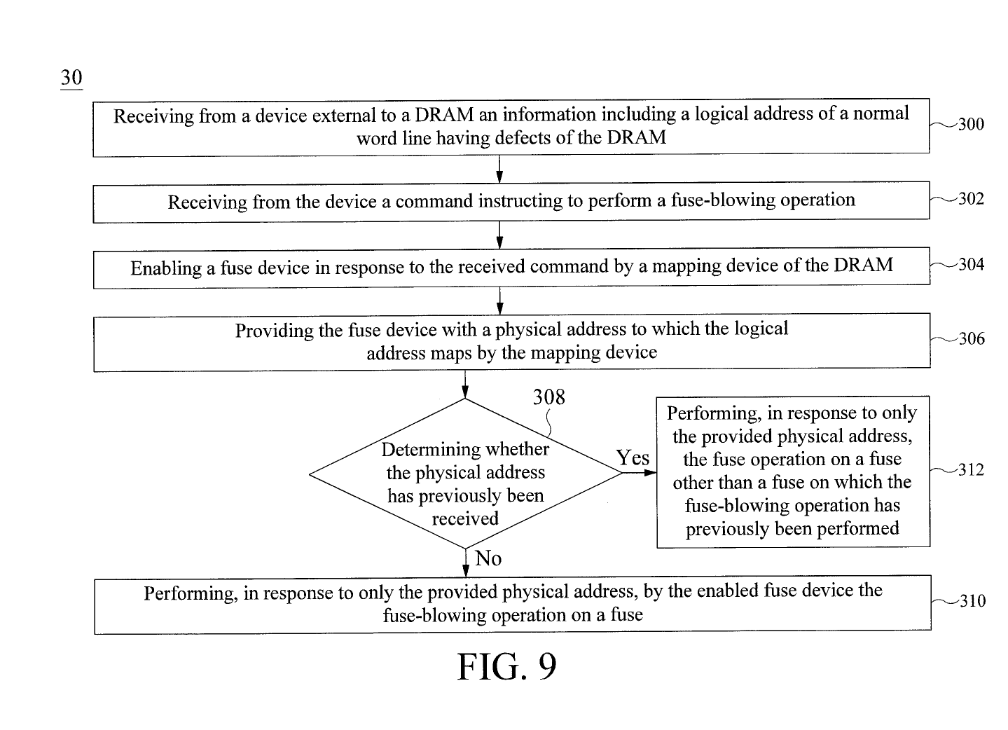

FIG. 9 is a flow diagram illustrating a method 30 of operating a fuse-blowing system of a DRAM, in accordance with some embodiments of the present disclosure. Referring to FIG. 9, the method 30 includes operations 300, 302, 304, 306, 308, 310 and 312.

Method 30 begins with operation 300, in which an information, including a logical address of a normal word line of the DRAM is received from a device external to the DRAM, wherein the normal word line contains defects.

Method 30 proceeds to operation 302, in which a command instructing to perform a fuse-blowing operation is received from the device.

Method 30 continues with operation 304, in which a fuse device is enabled by a mapping device of the DRAM in response to the received command.

Method 30 proceeds to operation 306, in which the fuse device is provided, by the mapping device, with a physical address to which the logical address maps.

Method 30 continues to operation 308, in which it is determined whether the physical address has been previously received. If negative, method 30 proceeds to operation 310 in which, in response to only the provided physical address, the enabled fuse device performs the fuse-blowing operation on a fuse. If affirmative, method 30 proceeds to operation 312 in which, in response to only the provided physical address, the fuse operation is performed on a fuse other than the fuse on which the fuse-blowing operation has been previously performed.

In the present disclosure, with the mapping device 22 functioning to map the logical address of a normal word line of the DRAM 20 to the physical address of the normal word line, even though a client never knows the physical address (i.e., the client is not able to provide the physical address to the DRAM 20) and only knows the logical address, the client still can perform the fuse-blowing operation to blow the fuse 16 by providing the logical address to the DRAM 20.

In contrast, during operation of the DRAM 10, for a client who does not possess physical addresses of the DRAM 10, and only possesses logical addresses, there is no way for the client to perform a fuse-blowing operation. Problems incurred by a normal word line that contains defects cannot be fixed. As a result, usage of the DRAM 10 is limited and less convenient for the client due to limitations of the design of the DRAM 10.

Moreover, in the present disclosure, as mentioned above the mapping device 22 is able to provide the fuse device 24 with the physical address of the normal word line. The fuse device 24 only requires the physical address provided by the mapping device 22 instead of being provided by the client to perform the fuse-blowing operation. Besides the physical address and the command, no other information or operations are required. Therefore, operations of the DRAM 20 are relatively simple.

In contrast, during operation of some DRAMs, in a post package repair (PPR) function, to perform an operation similar to the fuse-blowing operation mentioned above, a client must not only provide a logical address of a normal word line containing defects to the DRAMs, but also must provide a lot of additional information besides the logical address, and a lot of operations are required to be performed. In such DRAMs, the operations are relatively complicated.

One aspect of the present disclosure provides a fuse-blowing system of a dynamic random access memory (DRAM). The fuse-blowing system includes a fuse device and a mapping device. The mapping device, integrated with the fuse device in the DRAM, enables the fuse device, and provides the fuse device with a physical address. The enabled fuse device, in response to only the provided physical address, performs a fuse-blowing operation on a fuse of the DRAM.

Another aspect of the present disclosure provides a fuse-blowing system of a dynamic random access memory (DRAM). The fuse-blowing system includes a fuse device, a first fuse, a second fuse and a mapping device. The first fuse is fusible by the fuse device. The second fuse is fusible by the fuse device. The mapping device, integrated with the fuse device in the DRAM, enables the fuse device, and provides the fuse device with a physical address for a first time. The enabled fuse device, in response to only the provided physical address for the first time, performs a fuse-blowing operation on the first fuse. When the mapping device enables the fuse device and provides the fuse device with the physical address for a second time, the enabled fuse device, in response to only the provided physical address for the second time, performs the fuse-blowing operation on the second fuse.

Another aspect of the present disclosure provides a method of operating a fuse-blowing system of a DRAM. The method includes enabling a fuse device of the fuse-blowing system; providing the fuse device with a physical address; and performing, in response to only the provided physical address, a fuse-blowing operation on a fuse of the DRAM by the enabled fuse device.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

1. A fuse-blowing system of a dynamic random access memory (DRAM), the DRAM comprising a normal memory block, a redundant memory block and a fuse between a control line of the normal memory block and a redundant word line of the redundant memory block comprising:
a fuse device; and
a mapping device, integrated with the fuse device in the DRAM, configured to enable the fuse device and to provide the fuse device with a physical address of a word line of the normal memory block,
wherein the enabled fuse device, in response to only the provided physical address, performs a fuse-blowing operation on a fuse of the DRAM to cause the blown fuse to connect the redundant word line of the redundant memory block to the control line of the normal memory block.

2. The fuse-blowing system of claim 1, wherein the mapping device is further configured to receive, from a device external to the DRAM, an information including a logical address of a normal word line of the DRAM, wherein the normal word line contains defects, and the mapping device provides the fuse device with the physical address to which the logical address maps.

3. The fuse-blowing system of claim 2, wherein the mapping device is further configured to receive from the device a command instructing to perform the fuse-blowing operation, and the mapping device enables the fuse device in response to the received command.

4. The fuse-blowing system of claim 1, wherein the enabled fuse device is further configured to, in response to only the provided physical address, perform the fuse-blowing operation on the fuse when the provided physical address has not previously been received.

5. The fuse-blowing system of claim 1, wherein the enabled fuse device is further configured to, in response to only the provided physical address, and when the provided physical address has previously been received, perform the fuse-blowing operation on a fuse other than a fuse on which the fuse-blowing operation has been previously performed.

6. The fuse-blowing system of claim 5, wherein the fuse on which the fuse-blowing operation is performed is immediately adjacent to the fuse on which the fuse-blowing operation has been previously performed.

7. The fuse-blowing system of claim 6, wherein the fuse on which the fuse-blowing operation is performed is immediately adjacent to a fuse immediately adjacent to the fuse on which the fuse-blowing operation has been previously performed.

8. The fuse-blowing system of claim 1, wherein the DRAM includes a double-data-rate three synchronous dynamic random access memory (DDR3).

9. The fuse-blowing system of claim 1, wherein the fuse includes a laser-fusible fuse.

10. A fuse-blowing system of a dynamic random access memory (DRAM) the DRAM comprising a normal memory block, a redundant memory block and a fuse between a control line of the normal memory block and a redundant word line of the redundant memory block, comprising:
a fuse device;
a first fuse, fusible by the fuse device;
a second fuse, fusible by the fuse device; and
a mapping device, integrated with the fuse device in the DRAM, configured to enable the fuse device and to provide the fuse device with a physical address, of a word line of the normal memory block, for a first time,
wherein the enabled fuse device, in response to only the provided physical address for the first time, performs a fuse-blowing operation on the first fuse to cause the blown fuse to connect the redundant word line of the redundant memory block to the control line of the normal memory block, and
wherein when the mapping device enables the fuse device and provides the fuse device with the physical address for a second time, the enabled fuse device, in response to only the provided physical address for the second time, performs the fuse-blowing operation on the second fuse.

11. The fuse-blowing system of claim 10, wherein the mapping device is further configured to receive, from a device external to the DRAM, an information including a logical address of a normal word line of the DRAM, wherein the normal word line contains defects, and the mapping device provides the fuse device with the physical address to which the logical address maps.

12. The fuse-blowing system of claim 11, wherein the mapping device is further configured to receive from the device a command instructing to perform the fuse-blowing operation, and the mapping device enables the fuse device in response to the received command.

13. The fuse-blowing system of claim 10, wherein the second fuse is immediately adjacent to the first fuse.

14. The fuse-blowing system of claim 10, wherein the second fuse is immediately adjacent to a fuse immediately adjacent to the first fuse.

15. The fuse-blowing system of claim 10, wherein the DRAM includes a double-data-rate three synchronous dynamic random access memory (DDR3).

16. The fuse-blowing system of claim 10, wherein the fuse includes a laser-fusible fuse.

17. A method of operating a fuse-blowing system of a DRAM the DRAM comprising a normal memory block, a redundant memory block and a fuse between a control line of the normal memory block and a redundant word line of the redundant memory block, the method comprising:
enabling a fuse device of the fuse-blowing system;
providing the fuse device with a physical address of a word line of the normal memory block; and
performing, in response to only the provided physical address, a fuse-blowing operation on a fuse of the DRAM by the enabled fuse device to cause the blown fuse to connect the redundant word line of the redundant memory block to the control line of the normal memory block.

18. The method of claim 17, further comprising:
receiving from a device external to the DRAM an information including a logical address of a normal word line of the DRAM, wherein the normal word line contains defects; and
providing the fuse device with the physical address to which the logical address maps.

19. The method of claim 18, further comprising:
receiving from the device a command instructing to perform a fuse-blowing operation; and
enabling the fuse device in response to the received command.

20. The method of claim 19, further comprising:
performing, in response to only the provided physical address, the fuse-blowing operation on the fuse by the enabled fuse device when the provided physical address has not previously been received.
